(19) United States
(12) Patent Application Publication
(10) Pub. No.: US 2014/0315358 A1
(43) Pub. Date: Oct. 23, 2014

(54) MANUFACTURING METHOD OF JUNCTION FIELD EFFECT TRANSISTOR

(71) Applicants: Tsung-Yi Huang, HsinChu (TW); Chien-Hao Huang, Magong City (TW)

(72) Inventors: Tsung-Yi Huang, HsinChu (TW); Chien-Hao Huang, Magong City (TW)

(73) Assignee: RICHTEK TECHNOLOGY CORPORATION, Chupei City (TW)

(21) Appl. No.: 13/866,766

(22) Filed: Apr. 19, 2013

(51) Int. Cl. H01L 29/66

(52) U.S. Cl. CPC H01L 29/66893
USPC 438/196

(57) ABSTRACT

The present invention discloses a manufacturing method of a junction field effect transistor (JFET). The manufacturing method includes: providing a substrate with a first conductive type, forming a channel region with a second conductive type, forming a field region with the first conductive type, forming a gate with the first conductive type, forming a source with the second conductive type, forming a drain with the second conductive type, and forming a lightly doped region with the second conductive type. The channel region is formed by an ion implantation process step, wherein the lightly doped region is formed by masking a predetermined region from accelerated ions of the ion implantation process step, and diffusing impurities with the second conductive type nearby the predetermined region into it with a thermal process step.

### BACKGROUND OF THE INVENTION

1. Field of Invention

The present invention relates to a manufacturing method of a junction field effect transistor (JFET); particularly, it relates to such manufacturing method which adjusts a pinch-off voltage of the JFET by masking a predetermined region from accelerated ions in the ion implantation process step.

2. Description of Related Art

FIGS. 1A-1B show a prior art junction field effect transistor (JFET) 100 from cross-section view and top view respectively. As shown in FIGS. 1A-1B, the JFET 100 includes a substrate 11, a channel region 12, a field region 13, a gate 14, a source 15, a drain 16, and an isolation region 18. The substrate 11, the field region 13, and the gate 14 are P-type, and the channel region 12, the source 15, and the drain 16 are N-type. FIG. 1C shows N-type impurity concentration distribution along a dash line AA′ indicated in FIG. 1A. As shown in FIG. 1C, the N-type impurity concentration distributed along the dash line AA′ is constant, which indicates that the N-type impurities are distributed uniformly in the channel region 12. In a normal operation of the JFET 100, the sizes of depletion regions formed between the channel 12 and the field region 13 and between the channel 12 and the substrate 11 can be controlled by a voltage applied to the gate 14 to adjust the width of the channel region 12, such that a resistance between the source 15 and the drain 16 is controlled by the voltage applied to the gate 14. When an absolute value of a negative voltage applied to the gate 14 is higher than a threshold level, the channel region 12 is completely depleted, i.e., the channel region 12 is pinched off, and the threshold level is called a pinch-off voltage.

If it is required to form multiple JFETs with different pinch-off voltages in one substrate, in prior art, multiple lithography process steps and ion implantation process steps are required to form channels with different impurity concentrations in the multiple JFETs respectively. However, such prior art manufacturing method to form JFETs with different pinch-off voltages by multiple process steps has a high cost and longer manufacturing time.

Therefore, to overcome the drawbacks in the prior art, the present invention proposes a manufacturing method of a JFET, which adjusts the pinch-off voltage of the JFET by a simple process step, so that multiple JFETs with different pinch-off voltages can be formed on one substrate by a same process step, to reduce the manufacturing cost and manufacturing time.

### SUMMARY OF THE INVENTION

From one perspective, the present invention provides a manufacturing method of a junction field effect transistor (JFET) including: providing a substrate with a first conductive type, wherein the substrate has an upper surface; forming a channel region with a second conductive type in the substrate beneath the upper surface, wherein the second conductive type is opposite to the first conductive type; forming a field region with the first conductive type in the channel region beneath the upper surface; forming a gate with the first conductive type in the field region beneath the upper surface; forming a source with the second conductive type in the channel region beneath the upper surface, wherein the source is not located in the field region; forming a drain with the second conductive type in the channel region beneath the upper surface, wherein the drain is not located in the field region, and the drain and the source are at different sides of the field region without overlapping each other; and forming a lightly doped region with the second conductive type in the channel region between the gate and the drain, wherein the lightly doped region has a second conductive type impurity concentration which is lower than a second conductive type impurity concentration of the channel region; wherein the channel region is formed by an ion implantation process step, and the lightly doped region is formed by masking a predetermined region from accelerated ions of the ion implantation process step, and diffusing impurities with the second conductive type nearby the predetermined region into the predetermined region with a thermal process step.

In one preferable embodiment, the manufacturing method further includes: forming a plurality of isolation regions on the upper surface, which are between the source and the gate, and between the gate and the drain.

In the aforementioned embodiment, the isolation regions preferably include a local oxidation of silicon (LOCOS) structure or a shallow trench isolation (STI) structure.

In another preferable embodiment, the lightly doped region is adjacent to the field region.

In another preferable embodiment, the lightly doped region overlaps the field region.

From another perspective, the present invention provides a manufacturing method of a junction field effect transistor (JFET) including: providing a substrate with a first conductive type, wherein the substrate has an upper surface; forming a first channel region and a second channel region with a second conductive type in the substrate beneath the upper surface by a first same process step, wherein the first channel region and the second channel region do not overlap each other, and the second conductive type is opposite to the first conductive type; forming a first field region and a second channel region with the first conductive type in the first channel region and the second channel region respectively beneath the upper surface by a second same process step; forming a first gate and a second gate with the first conductive type in the first field region and the second field region respectively beneath the upper surface by a third same process step; forming a first source and a second source with the second conductive type in the first channel region and the second channel region respectively beneath the upper surface by a fourth same process step, wherein the first source and the second source are not located in the first field region or the second field region; forming a first drain and a second drain with the second conductive type in the first channel region and the second channel region respectively beneath the upper surface by a fifth same process step, wherein the first drain and the second drain are not located in the first field region or the second field region, and the first drain and the first source are at different sides of the first field region without overlapping each other, and the second drain and the second source are at different sides of the second field region without overlapping each other; and forming a first lightly doped region and a second lightly doped region with the second conductive type in the first channel region between the first gate and the first drain, and in the second channel region between the second gate and the second drain respectively by a sixth same process step, wherein the first lightly doped region and the second lightly doped region have second conductive type impurity concentrations which are lower than second conductive type impurity concentrations of the first channel region and the second channel region respectively; wherein the first same process step includes an ion implantation process step, and the first lightly doped region and the second lightly doped region are formed by masking at least one of a first predetermined region and a second predetermined region from accelerated ions of the ion implantation process step, and diffusing impurities with the second conductive type nearby the first predetermined region into the first predetermined region or the second predetermined region into the second predetermined region with a thermal process step.

In one preferable embodiment, the manufacturing method further includes: forming a plurality of first isolation regions and second isolation regions on the upper surface, wherein the plural first isolation regions are located between the first source and the first gate, and between the first gate and the first drain, and the plural second isolation regions are located between the second source and the second gate, and between the second gate and the second drain.

In the aforementioned embodiment, the first isolation region and the second isolation region preferably include a local oxidation of silicon (LOCOS) structure or a shallow trench isolation (STI) structure.

In one preferable embodiment, the first lightly doped region is adjacent to the first field region, and the second lightly doped region is adjacent to the second field region.

In one preferable embodiment, the first lightly doped region overlaps the first field region, and the second lightly doped region overlaps the second field region.

In one preferable embodiment, the first predetermined region and the second predetermined region have different sizes and both of the first predetermined region and the second predetermined region are masked from accelerated ions of the ion implantation process step.

The objectives, technical details, features, and effects of the present invention will be better understood with regard to the detailed description of the embodiments below.

### BRIEF DESCRIPTION OF THE DRAWINGS

FIGS. 1A-1C show a prior art JFET 100.

FIGS. 2A-2L show a first embodiment of the present invention.

FIGS. 3A-3C show a second embodiment of the present invention.

FIGS. 4A-4C show a third embodiment of the present invention.

FIGS. 5A-5F show a fourth embodiment of the present invention.

FIGS. 6A-6C show characteristic curves of an OFF breakdown voltage, a pinch-off voltage, and an ON breakdown voltage of a prior art JFET.

FIGS. 7A-7C show characteristic curves of an OFF breakdown voltage, a pinch-off voltage, and an ON breakdown voltage of a JFET according to the present invention.

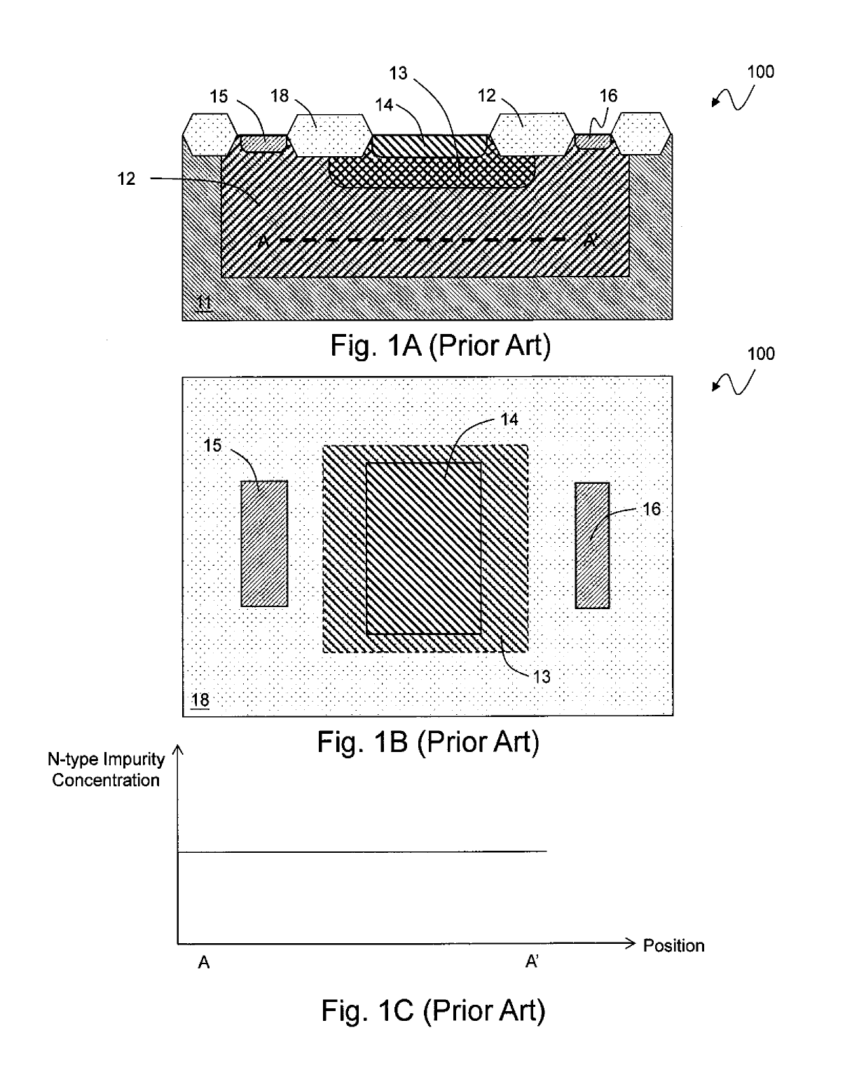

### DESCRIPTION OF THE PREFERRED EMBODIMENTS

The drawings as referred to throughout the description of the present invention are for illustration only, to show the interrelations between the regions and the process steps, but not drawn according to actual scale.

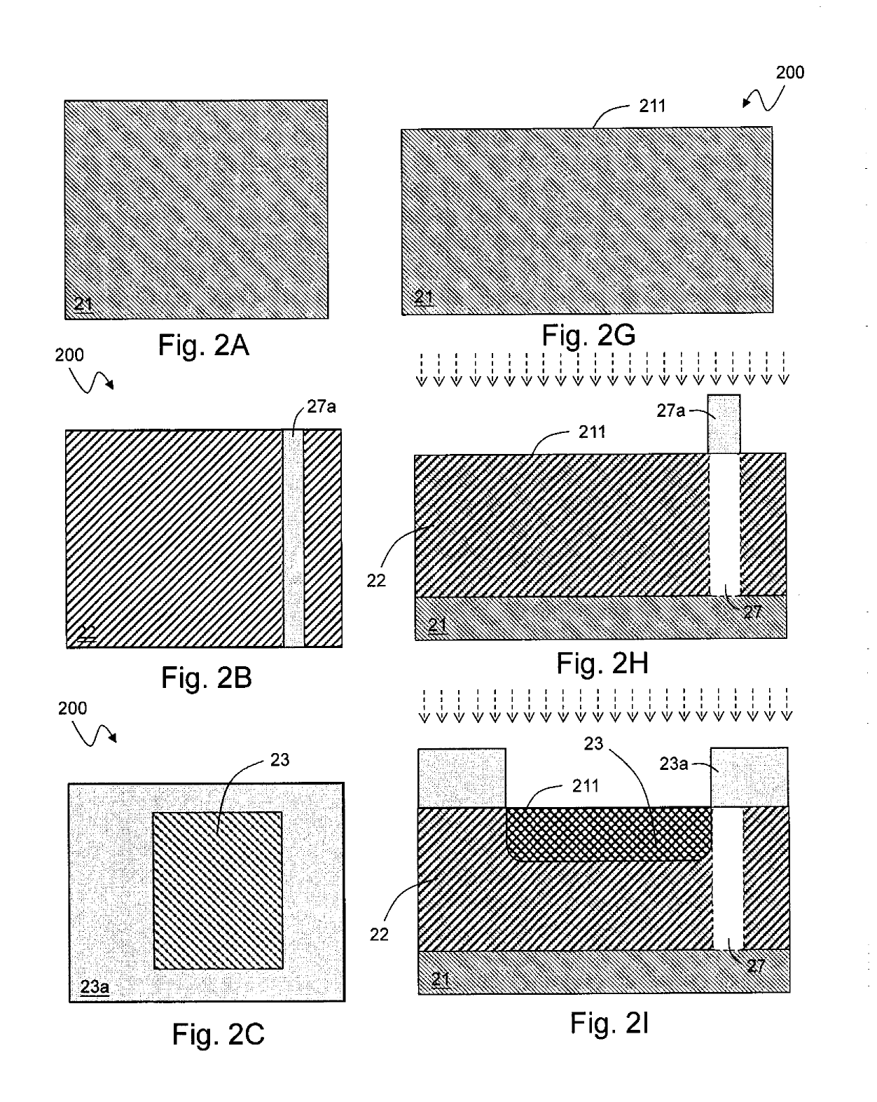

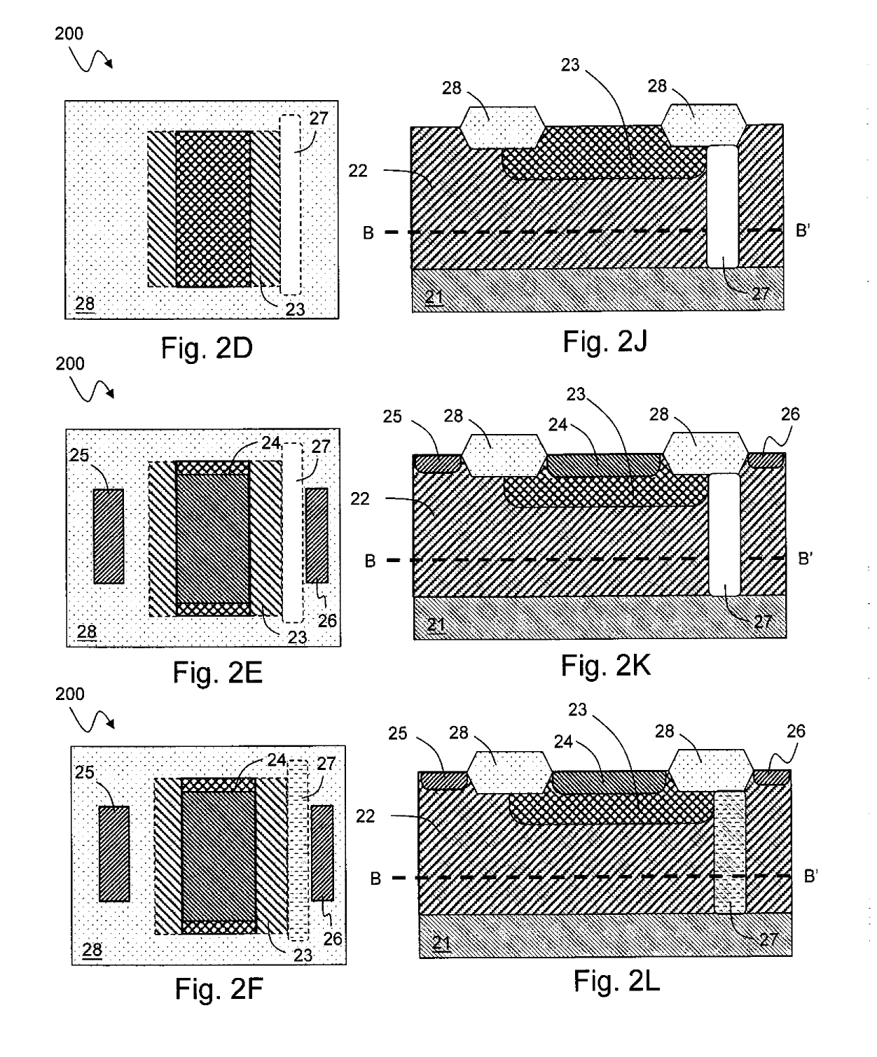

Please refer to FIGS. 2A-2L for a first embodiment according to the present invention, wherein FIGS. 2A-2F are top view schematic diagrams showing a manufacturing method of a junction field effect transistor (JFET) 200, and FIGS. 2G-2L are cross-section view schematic diagrams showing the manufacturing method of the JFET device 200. As shown in FIGS. 2A and 2G, first, a substrate 21 is provided, wherein the substrate 21 has an upper surface 211 and has a conductive type for example but not limited to P-type. Next, as shown in FIGS. 2B and 2H, a channel region 22 is formed in the substrate 21 beneath the upper surface 211. The channel region 22 has a conductive type for example but not limited to N-type, which is opposite to P-type. As shown in FIGS. 2B and 2H, a photoresist layer 27a is formed by a lithography process step, for masking a region which is later to be formed as a lightly doped region 27 (as shown in FIG. 2H) from accelerated ions of an ion implantation process step. Next, the ion implantation process step implants N-type impurities to regions in the substrate 21 excluding the aforementioned lightly doped region 27 which is masked by the photoresist layer 27a, in the form of accelerated ions as indicated by the dashed arrow lines, to form the channel region 22 in the substrate 21 beneath the upper surface 211.

Next, as shown in FIGS. 2C and 2I, a photoresist layer 23a is formed to define a field region 23 by a lithography process step. Next, an ion implantation process step implants P-type impurities to the defined regions in the form of accelerated ions, as indicated by the dashed arrow lines shown in FIG. 2I, to form the P-type field region 23 in the channel region 22 beneath the upper surface 211. Next, as shown in FIGS. 2D and 2J, plural isolation regions 28 such as local oxidation of silicon (LOCOS) structures or shallow trench isolation (STI) structures on the upper surface 211 by for example but not limited to an oxidation process step. The plural isolation regions 28 are located between the later formed source 25 and the later formed gate 24, and between the gate 24 and the later formed drain 26 (referring to FIGS. 2E and 2K).

Next, as shown in FIGS. 2E and 2K, agate 24 is defined by a lithography process step (not shown), and the gate 24 is formed by an ion implantation process step, which implants P-type impurities to the defined regions in the form of accelerated ions, to form the gate 24 in the field region 23 beneath the upper surface 211. Next, as shown in FIGS. 2E and 2K, a source 25 and a drain 26 are defined by a lithography process step (not shown), and the source 25 and the drain 26 are formed by an ion implantation process step, which implants N-type impurities to the defined regions in the form of accelerated ions, to form the N-type source 25 and drain 26 in the channel region 22 beneath the upper surface 211. The source 25 and the drain 26 are not located in the field region 23, and the drain 26 and the source 25 are at different sides of the field region 23 without overlapping each other.

Next, as shown in FIGS. 2F and 2L, an N-type lightly doped region 27 is formed by diffusing N-type impurities nearby the lightly doped region 27 into the lightly doped region 27 in the channel region 22 with a thermal process step, wherein the lightly doped region 27 has an N-type impurity concentration which is lower than an N-type impurity concentration of the channel region 22.

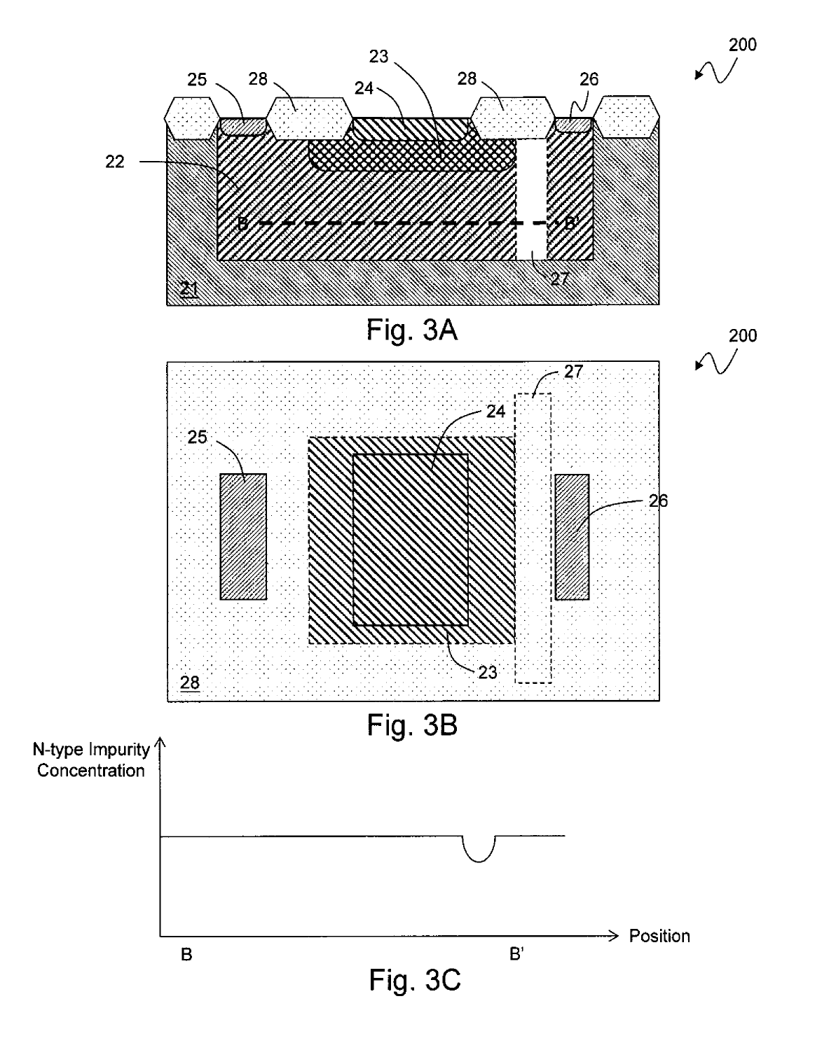

FIGS. 3A-3C show a second embodiment of the present invention, which illustrates the characteristics of the JFET 200 manufactured by the process according to the first embodiment. The N-type lightly doped region 27 is formed by masking part of the channel region 22 between the gate 24 and drain 26 in the ion implantation process step for forming the channel region 22, and diffusing N-type impurities nearby the lightly doped region 27 into the lightly doped region 27 with a thermal process step. The lightly doped region 27 has an N-type impurity concentration which is lower than the N-type impurity concentration of the channel region 22 as indicated by FIG. 3C, which shows the N-type impurity concentration distribution along a dashed line BB′ shown in FIG. 3A. According to the present invention, the pinch-off voltage of the JFET 200 is adjustable by adjusting the size of the lightly doped region 27. In this way, multiple JFETs with different pinch-off voltages can be formed in the same substrate 21 with a lower manufacturing cost and shorter manufacturing time. More specifically, the larger the masked area is, i.e., the larger the lightly doped region 27 is, the lower the absolute value of the pinch-off voltage of the JFET 200 is. The reason is thus: because the N-type impurity concentration of the lightly doped region 27 is lower than that of the channel region 22, when a voltage is applied to the gate 24, the depletion region formed at the lightly doped region 27 is wider than that formed at the channel region, and the channel is more easily pinched off (i.e., at a lower gate voltage) if the lightly doped region 27 is larger.

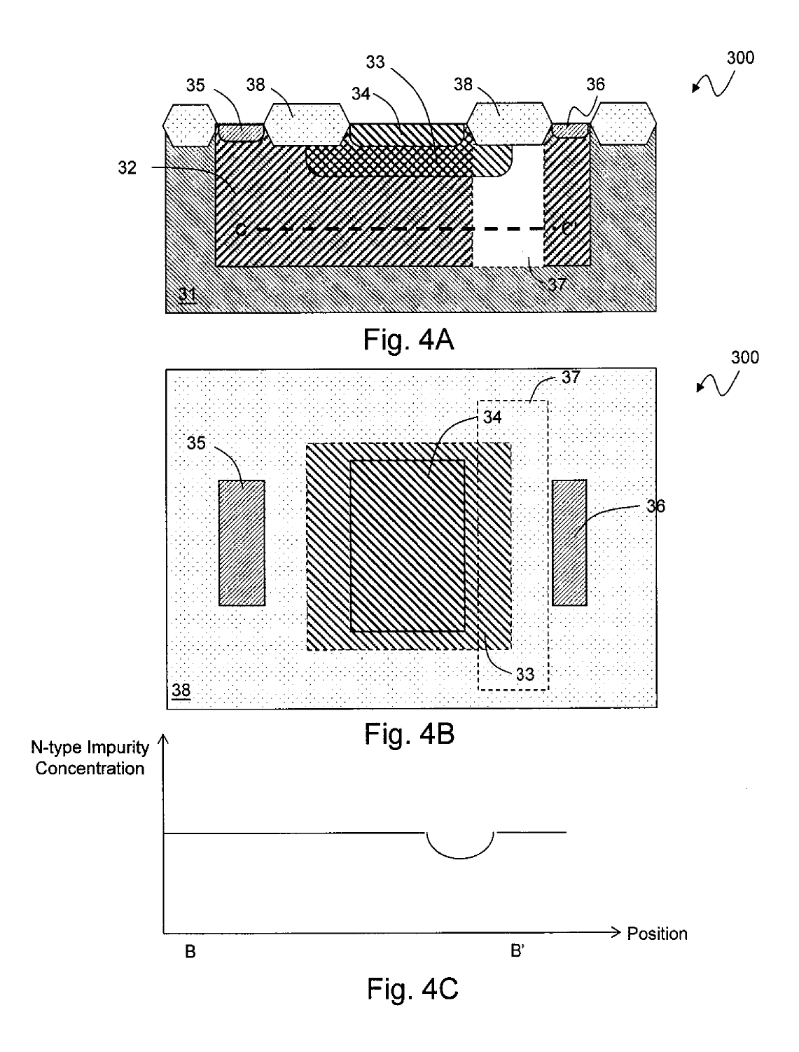

Please refer to FIGS. 4A-4C for a third embodiment according to the present invention. This embodiment shows a JFET 300 according to the present invention. The JFET 300 includes a P-type substrate 31, an N-type channel region 32, a P-type field region 33, a P-type gate 34, an N-type source 35, an N-type drain 36, an N-type lightly doped region 37, and plural isolation regions 38. The N-type lightly doped region 37 is formed by masking part of the channel region 32 between the gate 34 and drain 36 from accelerated ions in the ion implantation process step for forming the channel region 32, and diffusing N-type impurities nearby the lightly doped region 37 into the lightly doped region 37 with a thermal process step. The lightly doped region 37 has an N-type impurity concentration which is lower than the N-type impurity concentration of the channel region 32 as indicated by FIG. 4C, which shows the N-type impurity concentration distribution along a dashed line CC′ shown in FIG. 4A. This embodiment is different from the second embodiment in that, in the second embodiment, the lightly doped region 27 is adjacent to but not overlapping the field region 23, while in this embodiment, the lightly doped region 37 overlaps the field region 33. The overlapping part may have the same conductive type as the field region 33, which is P-type in this embodiment (i.e., the P-type concentration of the field region 33 is heavier than the N-type concentration of the lightly doped region 37 so the overlapping part presents P-type conductivity). This embodiment indicates that the lightly doped region may overlap the field region.

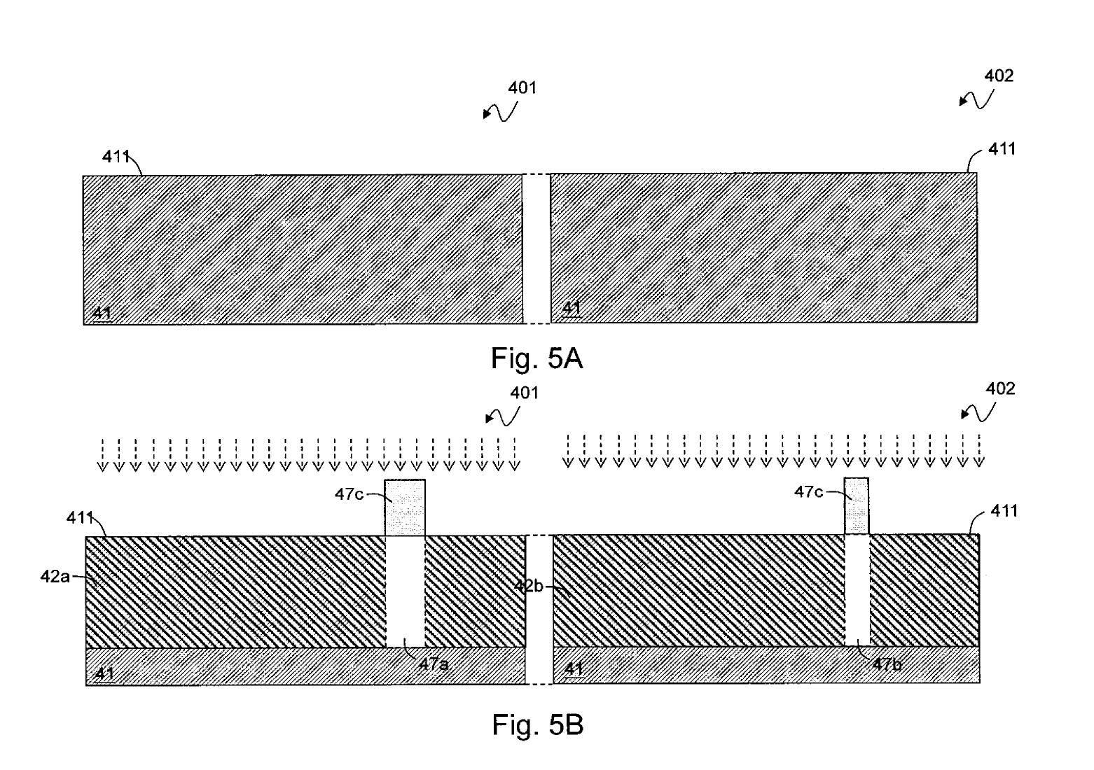

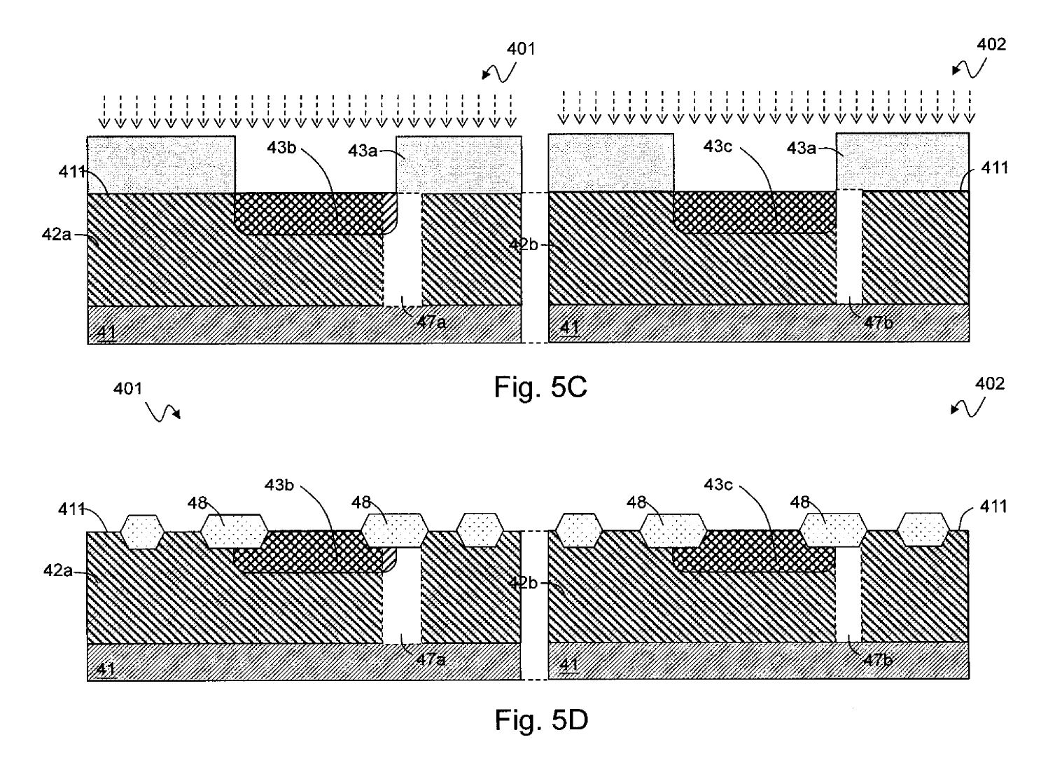

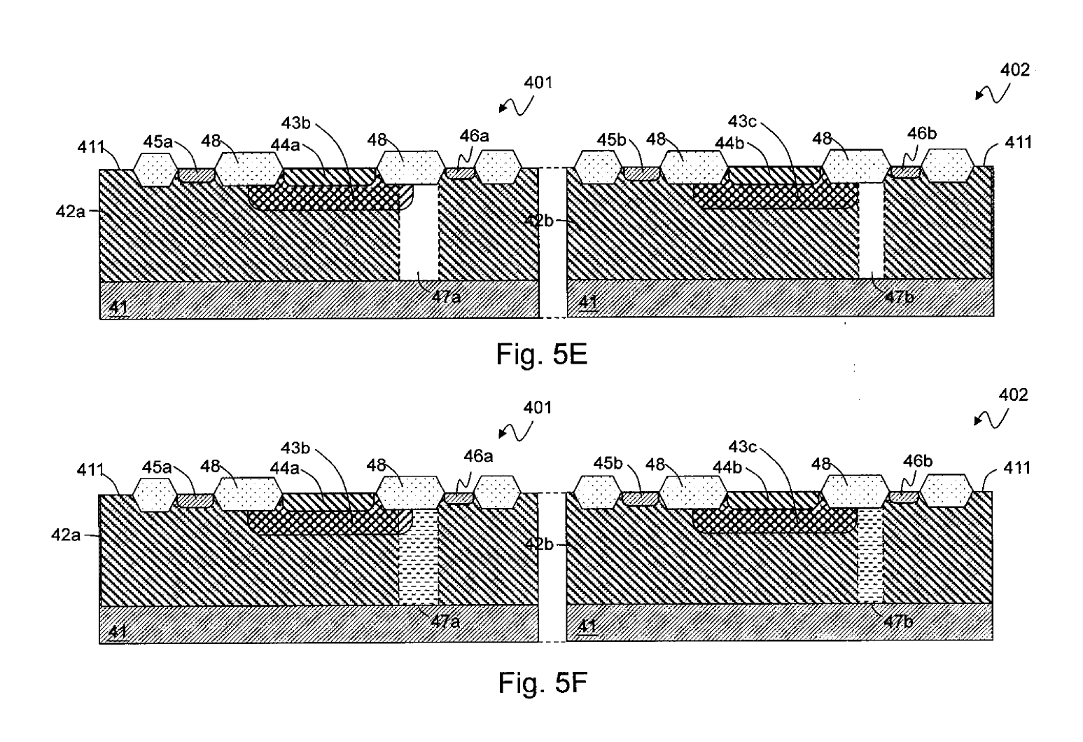

Please refer to FIGS. 5A-5F for a fourth embodiment according to the present invention, wherein FIGS. 5A-5F are cross-section view schematic diagrams showing a manufacturing method of JFETs 401 and 402 in a same substrate 41 by the same process steps. The JFETs 401 and 402 are manufactured in the same substrate 41 at different locations, but for illustration purpose, they are shown at left and right sides in the FIGS. 5A-5F, and separated by horizontal dashed lines. First, as shown in FIG. 5A, the substrate 41 with for example but not limited to P-type is provided, wherein the substrate 41 has an upper surface 411. Next, as shown in FIG. 5B, channel regions 42a and 42b of JFETs 401 and 402 are formed in the substrate 41 beneath the upper surface 411. The channel regions 42a and 42b have a conductive type for example but not limited to N-type, which is opposite to P-type. As shown in FIG. 5B, a photoresist layer 47c is formed by a lithography process step, for masking regions which are later to be formed as lightly doped regions 47a and 47b of JFETs 401 and 402 from accelerated ions of a following ion implantation process step. Next, the ion implantation process step implants N-type impurities to regions in the substrate 41 excluding the aforementioned lightly doped regions 47a and 47b which are masked by the photoresist layer 47c, in the form of accelerated ions as indicated by the dashed arrow lines, to form the N-type channel regions 42a and 42b in the substrate 41 beneath the upper surface 411.

Next, as shown in FIG. 5C, a photoresist layer 43a is formed to define field regions 43b and 43c by a lithography process step. Next, anion implantation process step implants P-type impurities to the defined regions in the form of accelerated ions as indicated by the dashed arrow lines shown in FIG. 5C, to form the P-type field regions 43b and 43c in the channel regions 42a and 42b respectively beneath the upper surface 411. Next, as shown in FIG. 5D, plural isolation regions 48 such as LOCOS structures or STI structures are formed on the upper surface 411 by for example but not limited to an oxidation process step. The plural isolation regions 48 are located between the later formed source 45a and gate 44a, source 45b and gate 44b, gate 44a and drain 46a, and gate 44b and drain 46b respectively (referring to FIG. 5E).

Next, as shown in FIG. 5E, gates 44a and 44b of the JFETs 401 and 402 are defined by a lithography process step (not shown), and the gates 44a and 44b are formed by an ion implantation process step, which implants P-type impurities to the defined regions in the form of accelerated ions, to form the gates 44a and 44b in the field regions 43b and 43c respectively beneath the upper surface 411. Next, as shown in FIG. 5E, sources 45a and 45b of the JFETs 401 and 402 and drains 46a and 46b of the JFETs 401 and 402 are defined by a lithography process step (not shown), and the sources 45a and 45b and the drains 46a and 46b are formed by an ion implantation process step, which implants N-type impurities to the defined regions in the form of accelerated ions, to form the N-type sources 45a and 45b and drains 46a and 46b in the channel regions 42a and 42b respectively beneath the upper surface 411. The sources 45a and 45b and the drains 46a and 46b are not located in the field region 43b or 43c, and the drains 46a and 46b and the sources 45a and 45b are at different sides of the field regions 43b and 43c respectively without overlapping each other.

Next, as shown in FIG. 5F, N-type lightly doped regions 47a and 47b are formed by diffusing N-type impurities nearby the lightly doped regions 47a and 47b into the lightly doped regions 47a and 47b in the channel regions 42a and 42b with a thermal process step, wherein the lightly doped regions 47a and 47b has an N-type impurity concentration which is lower than an N-type impurity concentration of the channel regions 42a and 42b.

Note that, in this embodiment, the photoresist layer 47c masks predetermined regions in both the JFETs 401 and 402 to define the lightly doped regions 47a and 47b of the JFETs 401 and 402. But the present invention is not limited to this; in another embodiment, the photoresist layer 47c may mask one or more predetermined regions in only one of the JFETs 401 and 402 but completely open the other of the JFETs 401 and 402, which can still form different JFETs 401 and 402 with different pinch-off voltages.

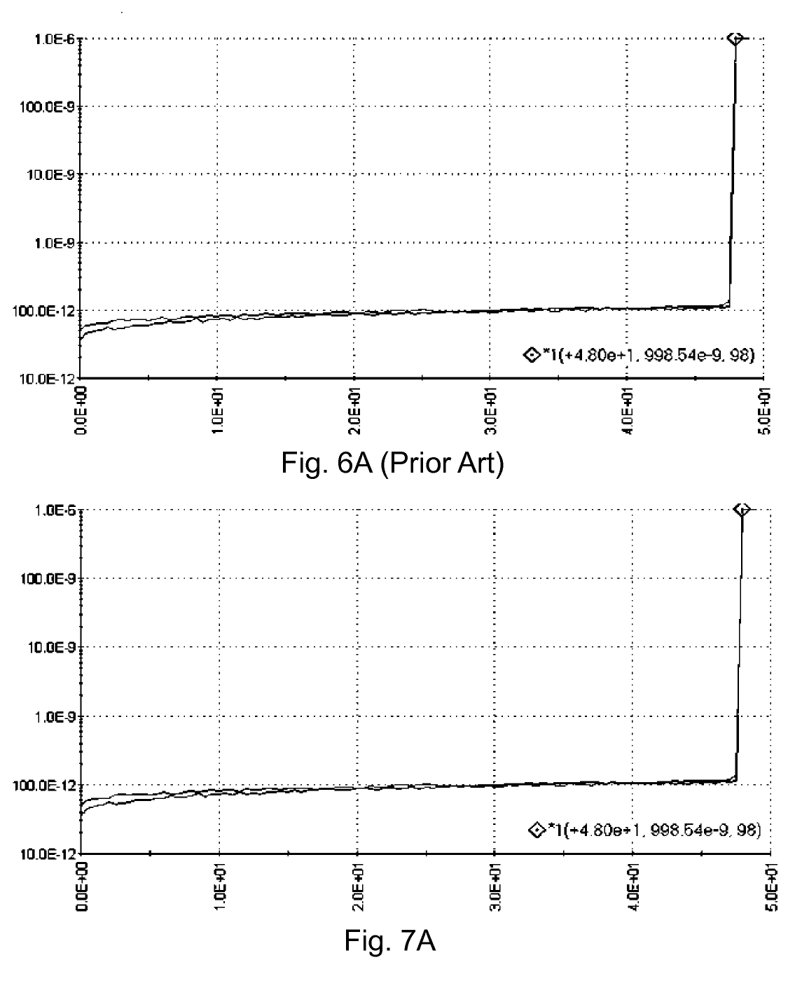

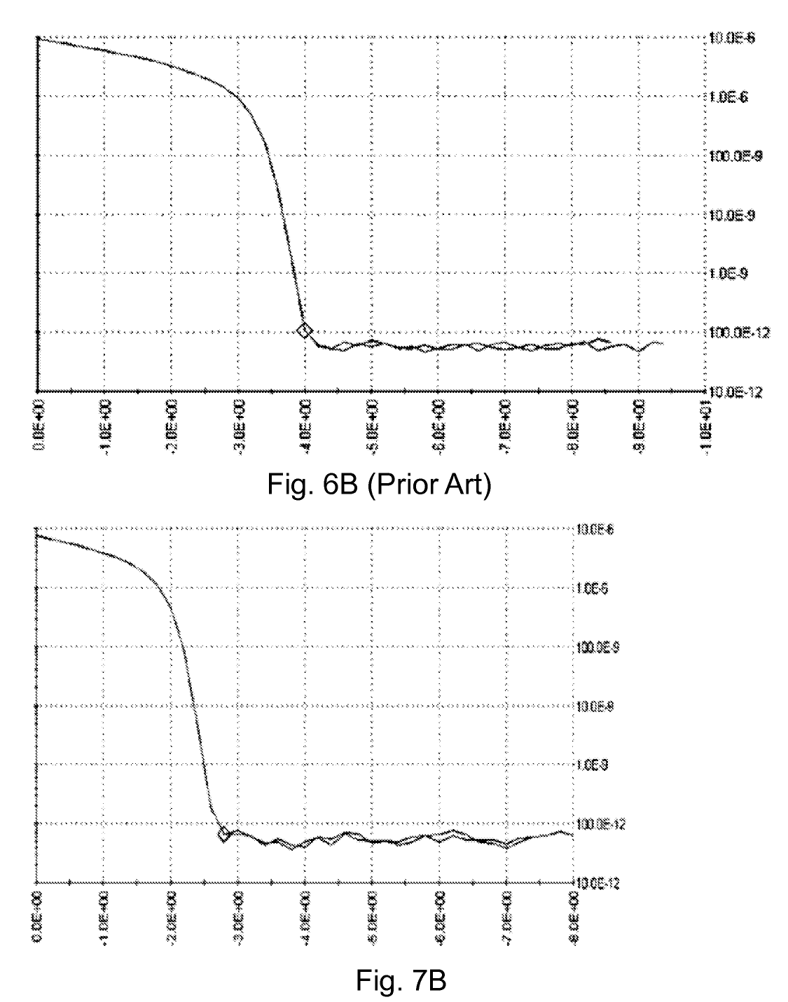

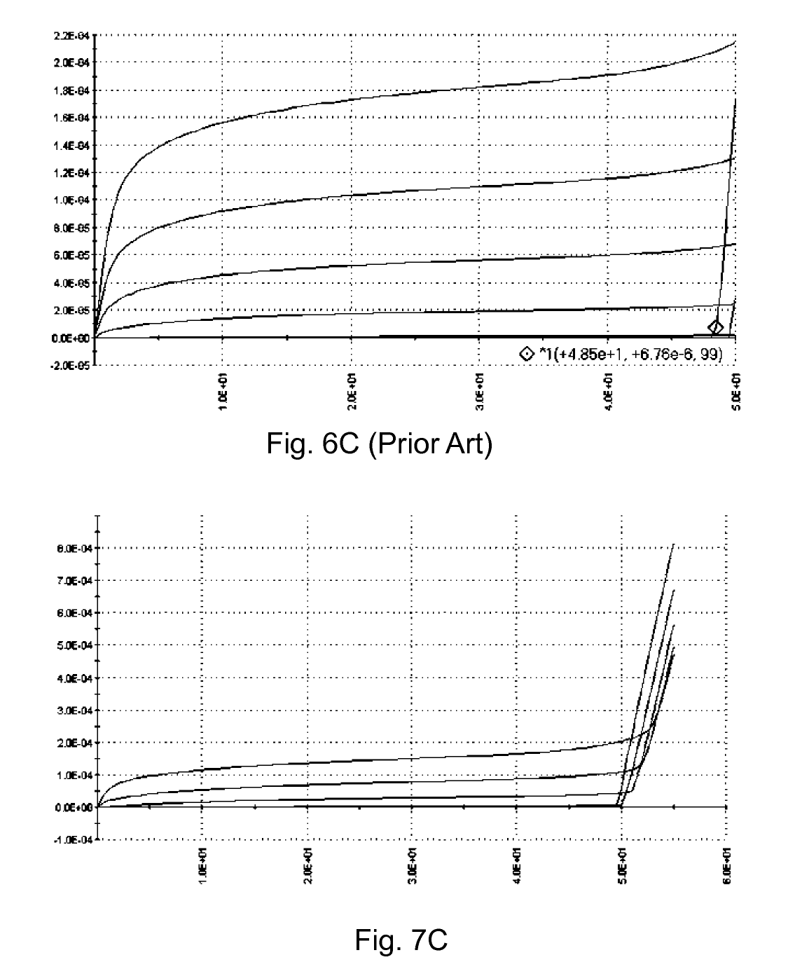

FIGS. 6A-6C show characteristic curves of OFF breakdown voltage, pinch-off voltage, and ON breakdown voltage of a prior art JFET. FIGS. 7A-7C show characteristic curves of OFF breakdown voltage, pinch-off voltage, and ON breakdown voltage of a JFET according to the present invention, wherein the JFET according to the present invention is located in a same substrate as the prior JFET which has the characteristic curves shown in FIGS. 6A-6C. Comparing FIGS. 6A and 7A, both the OFF breakdown voltages of the prior art JFET and the present invention JFET are about 48V. Comparing FIGS. 6B and 7B, the pinch-off voltage of the prior art JFET is about −4V, and the pinch-off voltage of the present invention JFET is about −2.7V. This indicates that different JFETs formed in a same substrate by the same process steps may have different pinch-off voltage according to the present invention. Comparing FIGS. 6C and 7C, both the ON breakdown voltages of the prior art JFET and the present invention JFET are about higher than 50V. This indicates that the characteristics of the JFET according to the present invention are not changed besides the pinch-off voltage.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other process steps or structures which do not affect the primary characteristic of the device, such as a threshold voltage adjustment region, etc., can be added; for another example, the lithography step described in the above can be replaced by electron beam lithography, X-ray lithography, etc.; for another example, in all the aforementioned embodiments, the conductive type of each region is not limited to P-type (or N-type), but it may be changed to N-type (or P-type) with conductive type and/or impurity concentration modifications in other regions; for another example, in the embodiment of FIGS. 5A-5F, the lightly doped regions 47a and 47b can overlap the field regions 43b and 43c. In view of the foregoing, the spirit of the present invention should cover all such and other modifications and variations, which should be interpreted to fall within the scope of the following claims and their equivalents. An embodiment or a claim of the present invention does not need to achieve all the objectives or advantages of the present invention. The title and abstract are provided for assisting searches but not for limiting the scope of the present invention.

What is claimed is:

1. A manufacturing method of a junction field effect transistor (JFET) comprising:
providing a substrate with a first conductive type, wherein the substrate has an upper surface;
forming a channel region with a second conductive type in the substrate beneath the upper surface, wherein the second conductive type is opposite to the first conductive type;
forming a field region with the first conductive type in the channel region beneath the upper surface;
forming a gate with the first conductive type in the field region beneath the upper surface;
forming a source with the second conductive type in the channel region beneath the upper surface, wherein the source is not located in the field region;
forming a drain with the second conductive type in the channel region beneath the upper surface, wherein the drain is not located in the field region, and the drain and the source are at different sides of the field region without overlapping each other; and
forming a lightly doped region with the second conductive type in the channel region between the gate and the drain, wherein the lightly doped region has a second conductive type impurity concentration which is lower than a second conductive type impurity concentration of the channel region;
wherein the channel region is formed by an ion implantation process step, and the lightly doped region is formed by masking a predetermined region from accelerated ions of the ion implantation process step, and diffusing impurities with the second conductive type nearby the predetermined region into the predetermined region with a thermal process step.

2. The manufacturing method of claim 1, further comprising: forming a plurality of isolation regions on the upper surface, which are between the source and the gate, and between the gate and the drain.

3. The manufacturing method of claim 2, wherein the isolation regions include a local oxidation of silicon (LOCOS) structure or a shallow trench isolation (STI) structure.

4. The manufacturing method of claim 1, wherein the lightly doped region is adjacent to the field region.

5. The manufacturing method of claim 1, wherein the lightly doped region overlaps the field region.

6. A manufacturing method of a junction field effect transistor (JFET) comprising:
providing a substrate with a first conductive type, wherein the substrate has an upper surface;
forming a first channel region and a second channel region with a second conductive type in the substrate beneath the upper surface by a first same process step, wherein the first channel region and the second channel region do not overlap each other, and the second conductive type is opposite to the first conductive type;
forming a first field region and a second channel region with the first conductive type in the first channel region and the second channel region respectively beneath the upper surface by a second same process step;
forming a first gate and a second gate with the first conductive type in the first field region and the second field region respectively beneath the upper surface by a third same process step;
forming a first source and a second source with the second conductive type in the first channel region and the second channel region respectively beneath the upper surface by a fourth same process step, wherein the first source and the second source are not located in the first field region or the second field region;
forming a first drain and a second drain with the second conductive type in the first channel region and the second channel region respectively beneath the upper surface by a fifth same process step, wherein the first drain and the second drain are not located in the first field region or the second field region, and the first drain and the first source are at different sides of the first field region without overlapping each other, and the second drain and the second source are at different sides of the second field region without overlapping each other; and
forming a first lightly doped region and a second lightly doped region with the second conductive type in the first channel region between the first gate and the first drain, and in the second channel region between the second gate and the second drain respectively by a sixth same process step, wherein the first lightly doped region and the second lightly doped region have second conductive type impurity concentrations which are lower than second conductive type impurity concentrations of the first channel region and the second channel region respectively;
wherein the first same process step includes an ion implantation process step, and the first lightly doped region and the second lightly doped region are formed by masking at least one of a first predetermined region and a second predetermined region from accelerated ions of the ion implantation process step, and diffusing impurities with the second conductive type nearby the first predetermined region into the first predetermined region or the second predetermined region into the second predetermined region with a thermal process step.

7. The manufacturing method of claim 6, further comprising forming a plurality of first isolation regions and second isolation regions on the upper surface, wherein the plural first isolation regions are located between the first source and the first gate, and between the first gate and the first drain, and the plural second isolation regions are located between the second source and the second gate, and between the second gate and the second drain.

8. The manufacturing method of claim 7, wherein the first isolation region and the second isolation region include a local oxidation of silicon (LOCOS) structure or a shallow trench isolation (STI) structure.

9. The manufacturing method of claim 6, wherein the first lightly doped region is adjacent to the first field region, and the second lightly doped region is adjacent to the second field region.

10. The manufacturing method of claim 6, wherein the first lightly doped region overlaps the first field region, and the second lightly doped region overlaps the second field region.

11. The manufacturing method of claim 6, wherein the first predetermined region and the second predetermined region have different sizes and both of the first predetermined region and the second predetermined region are masked from accelerated ions of the ion implantation process step.
